(19) United States
(12) Patent Application Publication
(10) Pub. No.: US 2024/0170613 A1
(43) Pub. Date: May 23, 2024

(54) OPTOELECTRONIC SEMICONDUCTOR ELEMENT

(71) Applicant: UNIKORN SEMICONDUCTOR CORPORATION, Hsinchu (TW)

(72) Inventors: Ching-En Huang, Hsinchu (TW); Chuang-Sheng Lin, Hsinchu (TW); Hao-Ming Ku, Hsinchu (TW); Shih-I Chen, Hsinchu (TW)

(21) Appl. No.: 18/511,223

(22) Filed: Nov. 16, 2023

(30) Foreign Application Priority Data
Nov. 17, 2022 (TW) 111143967

(51) Int. Cl. H01L 33/38

(52) U.S. Cl. CPC H01L 33/38

(57) ABSTRACT

An optoelectronic semiconductor element is provided. The optoelectronic semiconductor element includes a semiconductor stack and a first metal layer. The semiconductor stack includes a first portion and a second portion stacked in sequence, with the second portion including an active region. The first metal layer is located on the first portion and is electrically connected to the first portion. A top-view outline of the first portion shows a first pattern, a top-view outline of the second portion shows a second pattern, and a top-view outline of the first metal layer shows a third pattern. The area ratio of the third pattern to the first pattern is from 0.5% to 10%.

### CROSS REFERENCE TO RELATED APPLICATIONS

This application claims priority of Taiwan Patent Application No. 111143967 filed on Nov. 17, 2022, and the entirety of which is incorporated by reference herein.

### BACKGROUND

### Technical Field

The present disclosure relates to optoelectronic semiconductor element, and in particular it relates to an optoelectronic semiconductor element including a metal layer.

### Description of the Related Art

Semiconductor elements are widely used, and the research and development of related materials is also continuously being carried out. For example, III-V semiconductor materials containing group III and group V elements may be applied to various optoelectronic semiconductor elements, such as light-emitting chips (for example, light-emitting diodes or laser diodes), light-absorbing chips (photodetectors or solar cells) or non-luminous chips (for example, power components of switches or rectifiers), which can be used in lighting, medical treatment, display, communication, sensing, power supply systems and other applications.

With the advancements being made in science and technology, the volume of optoelectronic semiconductor elements has gradually been miniaturized. In recent years, due to breakthroughs in the size of light-emitting diodes (LEDs), micro-LED displays, which are made by arranging light-emitting diodes in an array, are gradually gaining attention in the market. Compared with organic light-emitting diode (OLED) displays, micro-LED displays are more power-efficient, have better reliability, longer service life and better contrast performance, while being visible in sunlight.

Although existing micro-LEDs can roughly meet their original intended use, they still do not fully meet requirements in all respects. In order to make sure the micro-LED has better device characteristics, product yield, and mass transfer stability at the device application end, the improvement of micro-LEDs is still a research topic in the industry.

### BRIEF SUMMARY

The present disclosure provides an optoelectronic semiconductor element. The optoelectronic semiconductor element includes a semiconductor stack and a first metal layer. The semiconductor stack includes a first portion and a second portion stacked in sequence, with the second portion including an active region. The first metal layer is located on the first portion and is electrically connected to the first portion. A top-view outline of the first portion shows a first pattern, a top-view outline of the second portion shows a second pattern, and a top-view outline of the first metal layer shows a third pattern. The area ratio of the third pattern to the first pattern is from 0.5% to 10%.

The present disclosure also provides another optoelectronic semiconductor element. The optoelectronic semiconductor element includes a semiconductor stack, a first metal layer, and a second metal layer. The semiconductor stack includes a first portion and a second portion, with the second portion including an active region. The first metal is electrically connected to the first portion. The second metal layer is electrically connected to the second portion. The semiconductor stack is located between the first metal layer and the second metal layer. A top-view outline of the first portion shows a first pattern, a top-view outline of the second portion shows a second pattern, a top-view outline of the first metal layer shows a third pattern, and a top-view outline of the second metal layer shows a fourth pattern. The area ratio of the fourth pattern to the first pattern is from 0.5% to 10%

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIG. 1 illustrates a top-view of an optoelectronic semiconductor element, in accordance with some embodiments of the present disclosure.

FIG. 2 illustrates a dimensional configuration of the optoelectronic semiconductor element, in accordance with some embodiments of the present disclosure.

FIG. 3A illustrates a top-view of the optoelectronic semiconductor element, in accordance with some embodiments of the present disclosure.

FIG. 3B illustrates a cross-sectional view of the optoelectronic semiconductor element, in accordance with some embodiments of the present disclosure.

FIG. 4A illustrates a top-view of a vertical type optoelectronic semiconductor element, in accordance with some embodiments of the present disclosure.

FIG. 4B illustrates a cross-sectional view of the vertical type optoelectronic semiconductor element, in accordance with some embodiments of the present disclosure.

FIGS. 5A and 5B illustrate schematic views of optoelectronic semiconductor elements bonded to carriers, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

By designing the structural appearance of the optoelectronic semiconductor element according to the embodiments of the present disclosure, the accuracy of the dimension and appearance of the element can be improved. For example, it is possible to reduce the appearance abnormality of the micro-LED chip and improve the product yield. Besides, the yield and stability of the micro-LED chip during mass transfer can also be improved.

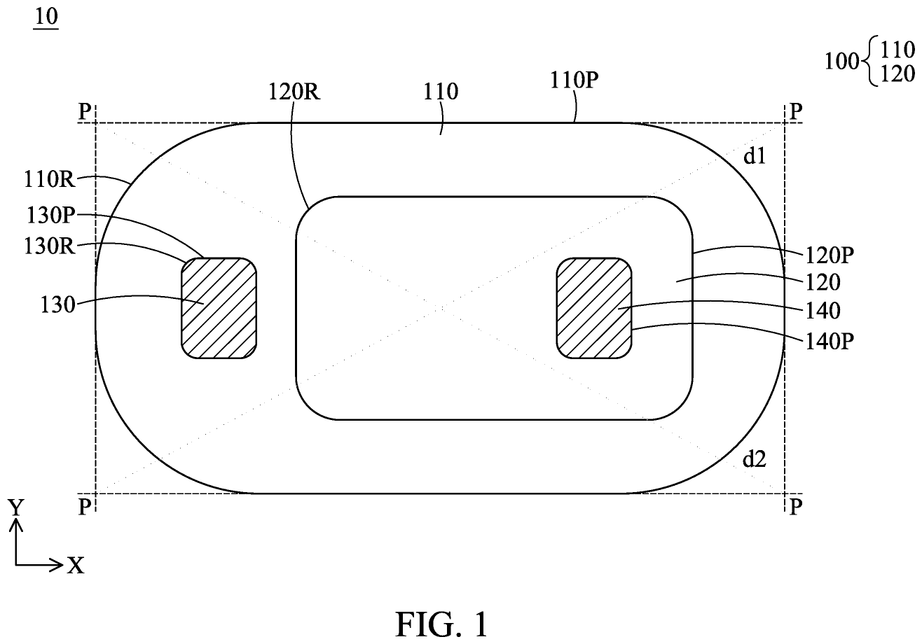

FIG. 1 is a top-view of an optoelectronic semiconductor element 10 in accordance with some embodiments of the present disclosure. The optoelectronic semiconductor element 10 may include a semiconductor stack 100, a first metal layer 130 and a second metal layer 140. In this embodiment, the first metal layer 130 and the second metal layer 140 of the optoelectronic semiconductor element 10 are configured laterally to form a horizontal type or flip-chip structure. That is, the first metal layer 130 and the second metal layer 140 are located on the same side of the semiconductor stack 100. In some embodiments, the semiconductor stack 100 includes a first portion 110 and a second portion 120 sequentially stacked along a stacking direction. More specifically, the second portion 120 is located on the first portion 110. In some embodiments, the first metal layer 130 is located on and electrically connected to the first portion 110. In some embodiments, the second metal layer 140 is located on and electrically connected to the second portion 120.

In some embodiments, as shown in FIG. 1, from a top view of the optoelectronic semiconductor element, the first portion 110 has a first pattern 110P, the second portion 120 has a second pattern 120P, the first metal layer 130 has a third pattern 130P, the fourth metal layer 140 has a fourth pattern 140P, and a first area ratio of the third pattern 130P to the first pattern 110P is from 0.5% to 10%. In some embodiments, the fourth pattern 140P is located within the second pattern 120P, and the second pattern 120P and the third pattern 130P are located within the first pattern 110P. In other words, the fourth pattern 140P overlaps with the second pattern 120P in the stacking direction of the semiconductor stack 100, and the second pattern 120P and the third pattern 130P overlap with the first pattern 110P in the stacking direction of the semiconductor stack 100.

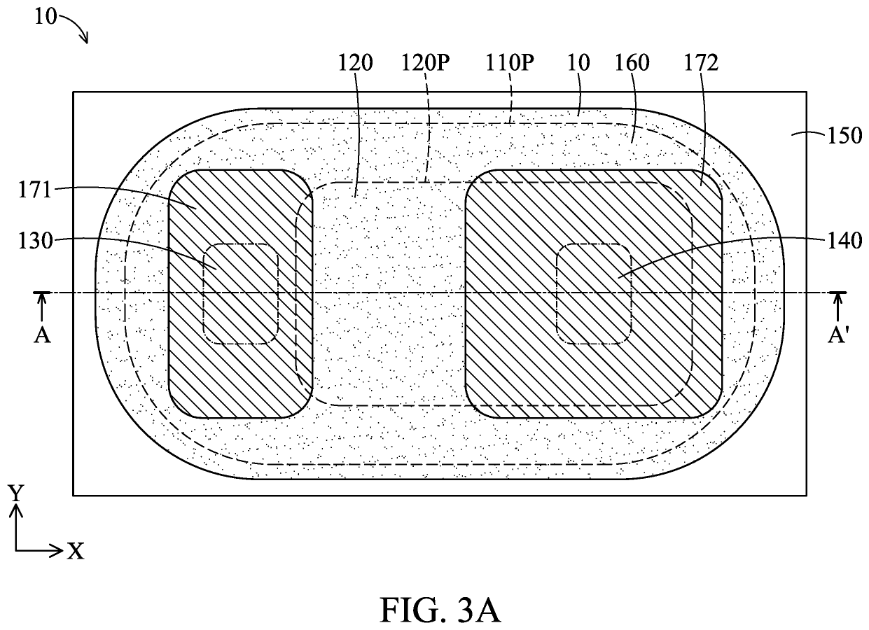

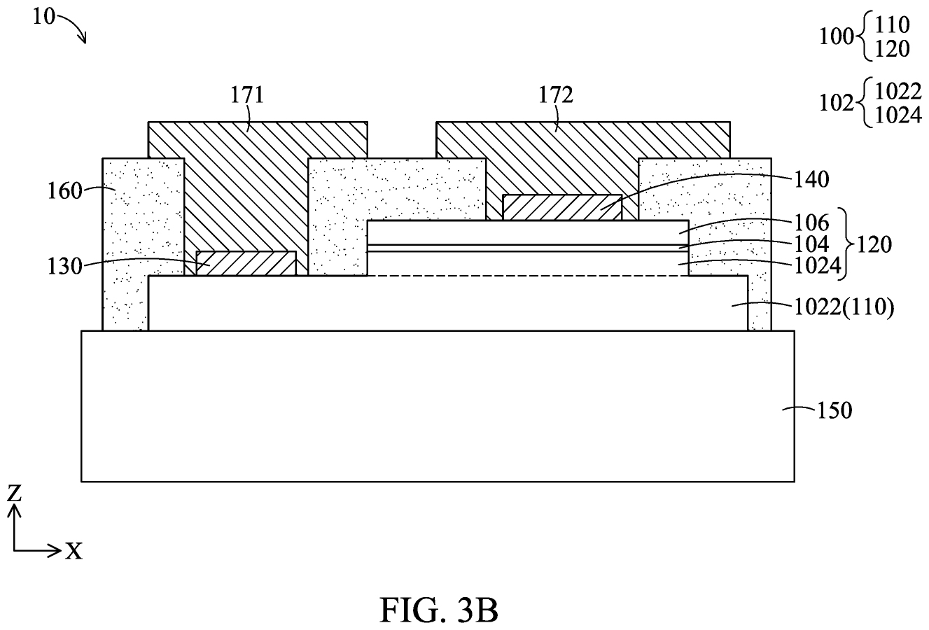

The optoelectronic semiconductor element 10 may be a micro-LED element or other suitable elements. A micro-LED refers to a light-emitting diode with a size of micron (μm) level, such as below 100 μm, below 30 μm, or even below 10 μm. In some embodiments, the second portion 120 includes a light-emitting region (such as the active region 104 in FIG. 3B) therein. In some embodiments, the first portion 110 includes a non-light-emitting region.

In some embodiments, as shown in FIG. 1, a first area of the first pattern 110P is larger than a second area of the second pattern 120P, and the second area of the second pattern 120P is larger than a third area of the third pattern 130P. The first pattern 110P may have a long side in a first direction (such as the X direction shown in FIG. 1) and a short side in a second direction perpendicular to the first direction (such as the Y direction shown in FIG. 1), and the second portion 120 and the first metal layer 130 may be arranged side by side in the first direction. In other words, the second portion 120 overlaps with the first metal layer 130 along the first direction. As shown in FIG. 1, the second portion 120 and the first metal layer 130 may be separated from each other in the first direction.

As shown in FIG. 1, the first pattern 110P, the second pattern 120P, and the third pattern 130P may respectively have one rounded corner. In some embodiments, the third pattern 130P has rounded corner(s) and right corner(s). In some embodiments, the first pattern 110P has a first rounded corner 110R with a first curvature radius R1, and the second pattern 120P has a second rounded corner 120R with a second curvature radius R2, and R1≥R2. In some embodiments, the third pattern 130P has a third rounded corner 130R with a third curvature radius R3, and R1≥R3. With rounded corner(s) of the first portion 110 and the second portion 120 of the semiconductor stack 100, the light extraction efficiency of the optoelectronic semiconductor element 10 can be improved. At the same time, through the rounded corner(s) of the first metal layer 130, the situation of point discharge caused by excessive electric field concentration can also be reduced.

As shown in FIG. 1, the first pattern 110P is substantially rectangular (for example, a rectangle with rounded corners) and the third pattern 130P has the third rounded corners 130R. The first pattern 110P includes diagonals d1, d2 which do not overlap with the third pattern 130P. Furthermore, the first metal layer 130 spaces apart from the edge of the first portion 110 with a certain distance to ensure that the first metal layer 130 is located within the first portion 110. Therefore, it can prevent the first metal layer 130 from shifting out of the first portion 110. Through the above-mentioned design, it is possible to reduce the deformation and dimensional distortion of the appearance of the optoelectronic semiconductor element 10 due to process factors. In some embodiments, the precision of the size of the micro-LED chips can be improved, so that it is easier to pick up and transfer the micro-LED chips to an external substrate.

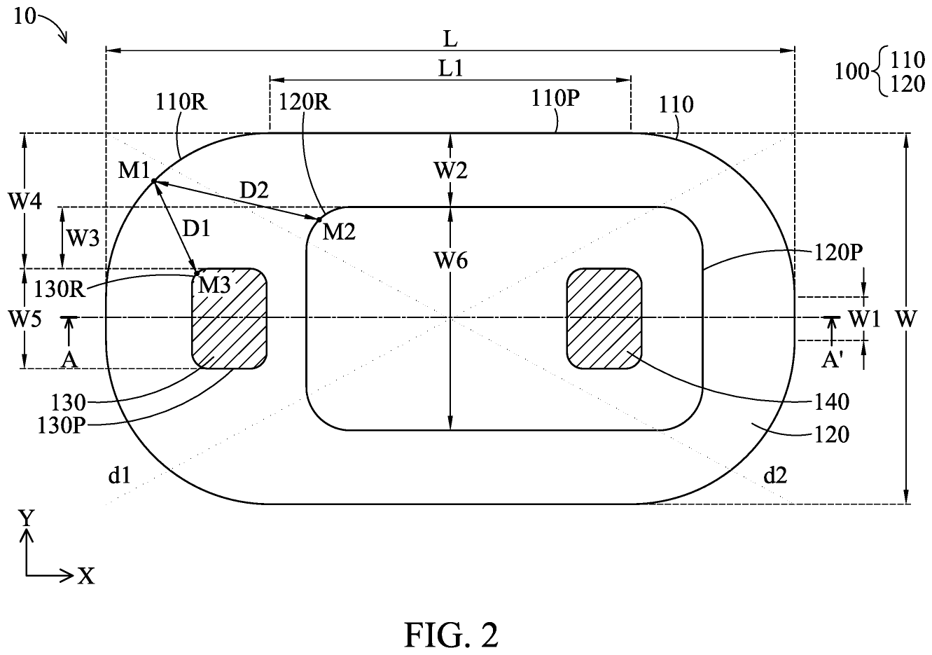

In the embodiment in which the first pattern 110P has the first rounded corners 110R, the diagonals d1 and d2 are defined as diagonal connections of intersections P of extension lines of the long side (corresponding to the first length L1 of FIG. 2) and the short side (corresponding to the first width W1 of FIG. 2) of the first pattern 110P.

In some embodiments, as shown in FIG. 1, the first metal layer 130 and the second metal layer 140 are located on the same side of the semiconductor stack 100. The first metal layer 130 and the second metal layer 140 may include suitable conductive materials, such as gold, silver, copper, tin-containing metals, indium-containing metals, or combinations thereof.

FIG. 2 is a dimensional configuration of the optoelectronic semiconductor element 10, in accordance with some embodiments of the present disclosure. It should be understood that the size of the optoelectronic semiconductor element 10 is defined by the size of the first pattern 110P. For example, in some embodiments, the maximum length and the maximum width of the optoelectronic semiconductor element 10 are defined as its size. In the embodiment, the maximum length refers to a device length L, and the maximum width refers to a device width W.

In some embodiments, the first pattern 110P includes two long sides with a first length L1 and two short sides with a first width W1. The first width W1 may be between 0 and 80 μm. When the first width W1 is 0, it represents two adjacent rounded corners 110R directly connected. In some embodiments, there is a second shortest distance W2 between the long side of the first pattern 110P and the outline of the second pattern 120P in the Y direction. There is a fourth shortest distance W4 between the long side of the first pattern 110P and the outline of the third pattern 130P in the Y direction, and W4≥W2. The second shortest distance W2 may be between 0.2 μm and 5 μm. The fourth shortest distance W4 may be between 0.5 μm and 6 μm. The ratio of the device width W to the fourth shortest distance W4 may be between 2.5 and 30.

In some embodiments, the first rounded corner 110R of the first pattern 110P is located between the long side and the short side. There is a first distance D1 between a first midpoint M1 of the first rounded corner 110R and a third midpoint M3 of the third rounded corner 130R. There is second distance D2 between the first midpoint M1 of the first rounded corner 110R and a second midpoint M2 of the second rounded corner 120R, and D2≥D1>0. The first curvature radius R1 of the first rounded corner 110R may be between 0.5 μm and 5 μm.

In some embodiments, the first rounded corner 110R of the first pattern 110P and the second rounded corner 120R of the second pattern 120P are staggered. In some embodiments, the first rounded corner 110R of the first pattern 110P and the third rounded corner 130R of the third pattern 130P are staggered. The so-called “staggered” here means that the extension of the connection line of the midpoints of two rounded corners of the pattern is not perpendicular to any of the two rounded corners of the other pattern. For example, the extension of the connection line of the first midpoint M1 and the second midpoint M2 is not perpendicular to any of the first rounded corner 110R and the second rounded corner 120R. The extension of the connection line of the first midpoints M1 and the third midpoint M3 is not perpendicular to any of the first rounded corner 110R and the third rounded corners 130R.

In some embodiments, the second pattern 120P has two long sides and two short sides, the long sides and the short sides are respectively parallel to the X direction and the Y direction, and the second rounded corner 120R of the second pattern 120P is between the long and short sides. The second curvature radius R2 of the second rounded corner 120R may be between 0.2 μm and 2 μm. In some embodiments, there is a third shortest distance W3 between the extension line of the long side of the second pattern 120P and the outline of the third pattern 130P in the Y direction, and W3≥W2. The ratio of the device width W to the second shortest distance W2 (W/W2) may be between 3 and 80. A preferable ratio of the device width W to the second shortest distance W2 is between about 15 and 30.

In some embodiments, the third pattern 130P has two long sides and two short sides, the long sides and the short sides are respectively parallel to the X direction and the Y direction, and the third rounded corner 130R is located between the long and short sides of the third pattern 130P. In some embodiments, the second pattern 120P has a sixth width W6, the third pattern 130P has a fifth width W5, and W6≥W5. In some embodiments, W>W6≥W1. The ratio of the device width W to the fifth width W5 (W/W5) may be between 1.1 and 10.

FIGS. 3A and 3B are top-view and cross-sectional view of the optoelectronic semiconductor element 10, respectively, in accordance with some embodiments of the present disclosure. FIG. 3B is the cross-sectional view corresponding to the line AA′ of FIG. 3A. In some embodiments, as shown in FIG. 3B, a substrate 150 is disposed below the semiconductor stack 100. The substrate 150 may be a native substrate for growing the semiconductor stack 100 thereon, or a non-native substrate for transferring the grown semiconductor stack 100. In some embodiments, the semiconductor stack 100 does not completely cover the substrate 150. In some embodiments, disposing the semiconductor stack 100 on the substrate 150 includes bonding the semiconductor stack 100 and the substrate 150 through an adhesive layer (not shown). The material of the adhesive layer may include benzocyclobutene (BCB), polyimide (PI), silicon dioxide (SiO₂), silicon nitride (SiNₓ), titanium dioxide (TiO₂), tantalum pentoxide (Ta₂O₅), aluminum oxide (Al₂O₃), or a combination of these materials.

In some embodiments, the substrate 150 includes an insulating material or a non-insulating material. The insulating material includes sapphire, glass, or ceramic material. Non-insulating materials include elemental semiconductors (such as silicon or germanium), compound semiconductors (such as silicon carbide, gallium arsenide, gallium nitride, aluminum nitride, aluminum gallium nitride, or combinations thereof), metals (such as copper, molybdenum, or copper tungsten), or a combination thereof. The substrate 150 may also be a multi-layered substrate, such as a silicon-on-insulator (SOI) substrate.

As shown in FIG. 3B, the semiconductor stack 100 includes a first-type semiconductor layer 102, an active region 104, and a second-type semiconductor layer 106 stacked along the stacking direction (Z direction). Specifically, the first portion 110 of the semiconductor stack 100 may include a lower portion 1022 of the first-type semiconductor layer 102, and the second portion 120 of the semiconductor stack 100 may include an upper portion 1024 of the first-type semiconductor layer 102, the active region 104, and the second-type semiconductor layer 106. The first-type semiconductor layer 102 and the second-type semiconductor layer 106 have different dopants to respectively provide electrons and holes, or respectively provide holes and electrons. The electrons and holes provided by the first-type semiconductor layer 102 and the second-type semiconductor layer 106 can recombine in the active region 104 to generate light. For example, the first-type semiconductor layer 102 may be an n-type semiconductor layer, and the second-type semiconductor layer 106 may be a p-type semiconductor layer, or the first-type semiconductor layer 102 may be a p-type semiconductor layer, and the second-type semiconductor layer 106 may be an n-type semiconductor layer.

The materials of the first-type semiconductor layer 102, the active region 104, and the second-type semiconductor layer 106 include III-V group semiconductor materials, such as AlₓIn_{y}Ga_{(1-x-y)}N, AlₓIn_{y}Ga_{(1-x-y)}As or AlₓIn_{y}Ga_{(1-x-y)}P, wherein 0≤x, y≤1, and (x+y)≤1. When the material of the active region 104 is InGaP or AlInGaP, the active region 104 can emit red light with a wavelength between 610 nm and 700 nm, or emit yellow light or green light with a wavelength between 510 nm and 600 nm. When the material of the active region 104 is InGaN, the active region 104 can emit blue light or deep blue light with a wavelength between 400 nm and 490 nm, or emit green light with a wavelength between 490 nm and 550 nm. When the material of the active region 104 is AlGaN or AlGaInN, the active region 104 can emit ultraviolet light with a wavelength between 250 nm and 400 nm. When the material of the active region 104 is InGaAs, InGaAsP, AlGaAs, or AlGaInAs, the active region 104 can emit infrared light with a wavelength between 700 nm and 1700 nm. The semiconductor stack 100 may include a single heterostructure (SH), a double heterostructure (DH), a double-side double heterostructure (DDH), or a multi-quantum well (MQW) material structure. The material of the active region 104 may be a semiconductor doped with p-type dopant, doped with n-type dopant, or without dopant. The p-type or n-type dopant may be magnesium (Mg), zinc (Zn), silicon (Si), carbon (C) or tellurium (Te).

The optoelectronic semiconductor element 10 may further include an insulating layer 160 disposed on the semiconductor stack 100, and there are at least two openings in the insulating layer 160 for exposing the first metal layer 130 and the second metal layer 140. Referring to FIG. 3B, an etching process may be performed on the insulating layer 160 to form at least two openings respectively exposing the first metal layer 130 on the first portion 110 and the second metal layer 140 on the second portion 120. FIG. 3A shows the first pattern 110P of the first portion 110 and the second pattern 120P of the second portion 120 under the insulating layer 160, respectively. The first pattern 110P and the second pattern 120P are indicated by dotted lines. In some embodiments, the openings respectively expose the upper surfaces of the first portion 110 and/or the second portion 120. In some embodiments, the insulating layer 160 covers the semiconductor stack 100 and a part of the substrate 150.

The material of the insulating layer 160 may include a non-conductive material. Non-conductive material includes organic material, inorganic material or dielectric material. Organic material includes benzocyclobutene (BCB), perfluorocyclobutane (PFCB), epoxy resin, acrylic resin, cycloolefin polymer (COC), polymethyl methacrylate (PMMA), polyethylene terephthalate (PET), polycarbonate (PC), polyetherimide, fluorocarbon polymer. Inorganic material includes silicone and glass. Dielectric material includes aluminum oxide (Al₂O₃), silicon nitride (SiNₓ), silicon oxide (SiOₓ), titanium oxide (TiOₓ), magnesium fluoride (MgFₓ).

The optoelectronic semiconductor element 10 may further include a first electrode 171 electrically connected to the first metal layer 130 and a second electrode 172 electrically connected to the second metal layer 140. The top surfaces of the first electrode 171 and the second electrode 172 may substantially be the same elevation. FIG. 3A shows the first metal layer 130 and the second metal layer 140 respectively located under the first electrode 171 and the second electrode 172, and the first metal layer 130 and the second metal layer 140 are indicated by dotted lines. In some embodiments, as shown in FIG. 3A, the areas of the first electrode 171 and the second electrode 172 are respectively larger than the areas of the first metal layer 130 and the second metal layer 140. By disposing the first electrode 171 and the second electrode 172 with larger areas, the first metal layer 130 and the second metal layer 140 can be electrically connected to external circuits more easily.

The first electrode 171 and the second electrode 172 may be a single-layer or multi-layer structure. The material of the first electrode 171 and the second electrode 172 may include conductive material, such as metal, metal compound, or a combination thereof. The metal includes, for example, gold, nickel, platinum, palladium, iridium, titanium, chromium, tungsten, aluminum, copper, silver, tin, indium, alloys thereof, or combinations thereof. The metal compound includes metal oxide (such as indium tin oxide (ITO)) or other light-transmitting conductive materials.

In some embodiments, as shown in FIG. 3B, the first electrode 171 and the second electrode 172 may be in direct contact with part of the semiconductor stack 100. More specifically, the first electrode 171 and the second electrode 172 directly contact with the upper surface of the first part 110 and/or the second part 120 and cover the sidewalls of the first metal layer 130 and/or the second metal layer 140, respectively. In the first direction (X direction), the active region 104 may locate between the first electrode 171 and the second electrode 172. That is, a portion of the active region 104 does not overlap the first electrode 171 and the second electrode 172 in the Z direction, so that the light can emit from the optoelectronic semiconductor element 100 through the space between the first electrode 171 and the second electrode 172. In some embodiments, as shown in FIG. 3B, the first electrode 171 overlaps with the first metal layer 130 in the Z direction, and the second electrode 172 overlaps with the second metal layer 140 in the Z direction.

With the structural appearance of the optoelectronic semiconductor element 10 according to the above embodiments, the accuracy of the dimension and appearance of each component can be improved. For example, the abnormal appearance of the optoelectronic semiconductor element 10 produced by lithography and etching processes can be reduced, and the product yield can be therefore improved. At the same time, the yield and stability of the optoelectronic semiconductor element during subsequent mass transfer can also be enhanced.

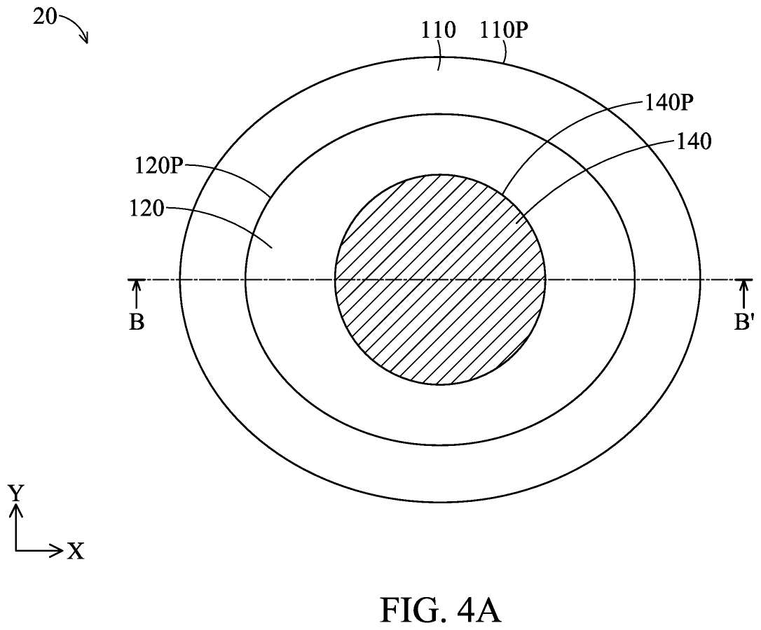

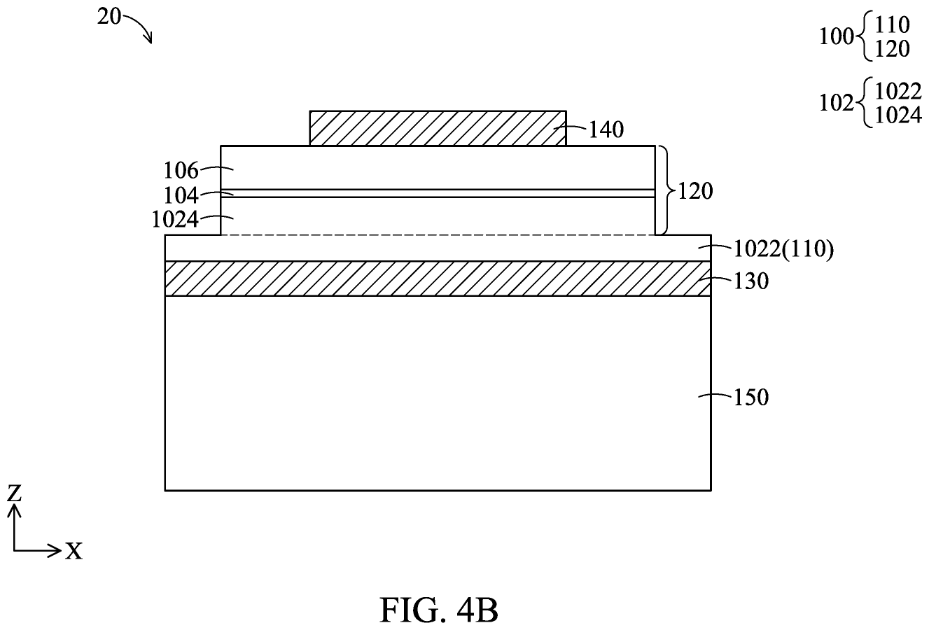

FIGS. 4A and 4B respectively are top-view and cross-sectional view of a vertical type optoelectronic semiconductor element 20, in accordance with some embodiments of the present disclosure. FIG. 4B is a cross-sectional view corresponding to the line BB′ of FIG. 4A. The so-called “vertical type” configuration means that the metal layers of the optoelectronic semiconductor element are located on the opposite sides of the semiconductor stack, or the metal layers form electrical connection with the semiconductor stack in vertical direction. The optoelectronic semiconductor element 20 includes components having the same reference numerals as the components in the optoelectronic semiconductor element 10. The components with the same reference numerals in the optoelectronic semiconductor element 10 and optoelectronic semiconductor element 20 may include similar materials and be formed with a similar process, and the detailed description thereof is omitted here for simplicity.

Referring to FIGS. 4A and 4B, the semiconductor stack 100 includes the first portion 110 and the second portion 120. In some embodiments, the first metal layer 130 is electrically connected to the first portion 110, the second metal layer 140 is electrically connected to the second portion 120. Different from the laterally configured optoelectronic semiconductor element 10, the semiconductor stack 100 of the optoelectronic semiconductor element 20 is located between the first metal layer 130 and the second metal layer 140. As shown in FIG. 4A, from the top-view of the optoelectronic semiconductor element 20, the first portion 110 has a first pattern 110P, the second portion 120 has a second pattern 120P, and the first metal layer 130 has a third pattern (not shown in FIG. 4A), and the second metal layer 140 has a fourth pattern 140P. A second area ratio of the fourth pattern 140P to the first pattern 110P is from 0.5% to 10%. In some embodiments, the second pattern 120P is located within the first pattern 110P. In some embodiments, the fourth pattern 140P is located within the second pattern 120P.

By disposing the first metal layer 130 and the second metal layer 140 on opposite sides of the semiconductor stack 100 to form a vertical type optoelectronic semiconductor element 20, the ratio of the active region 104 to be removed can be reduced so a larger luminous area can be preserved. By controlling the second area ratio of the fourth pattern 140P to the first pattern 110P, the abnormal appearance of the optoelectronic semiconductor element 20 produced by the lithography and etching process can be reduced and the product yield can be improved. At the same time, the yield and stability of the optoelectronic semiconductor element 20 during subsequent mass transfer can be enhanced.

In some embodiments, as shown in FIG. 4A, the first pattern 110P is circular or elliptical, and the first pattern 110P has a first curvature radius R1. In some embodiments, as shown in FIG. 4A, the second pattern 120P and the fourth pattern 140P are substantially circular or elliptical. The second pattern 120 has a second curvature radius R2, and the fourth pattern 140P has a fourth curvature radius R4. The first curvature radius R1 of the first pattern 110P is larger than the second curvature radius R2 of the second pattern 120P, and the first curvature radius R1 of the first pattern 110P is larger than the fourth curvature radius R4 of the fourth pattern 140P. In some embodiments, the third pattern 130P is substantially circular or elliptical, and the third pattern 130P has a third curvature radius R3, and the first curvature radius R1 of the first pattern 110P is larger than or equal to the third curvature radius R3 of the third pattern 130P.

When any of the first pattern 110P, the second pattern 120P, the third pattern 130P, and the fourth pattern 140P is substantially circular, its corresponding curvature radius R1, R2, R3, or R4 is a fixed value everywhere on the pattern. When any of the above patterns is substantially elliptical, its corresponding curvature radius R1, R2, R3, or R4 is a variable value on the pattern. In some embodiments, as shown in FIG. 4A, the first pattern 110P, the second pattern 120P, and the fourth pattern 140P have corresponding outlines. In some embodiments, the first pattern 110P, the second pattern 120P, and the fourth pattern 140P are substantially circular and concentric to each other.

Referring to FIG. 4B, the first metal layer 130 may be disposed between the semiconductor stack 100 and the substrate 150. In some embodiments, there is no substrate 150 under the first metal layer 130, and therefore, a lower surface of the first metal layer 130 is exposed. In this way, the lower surface of the first metal layer 130 can be electrically connected to an external circuit.

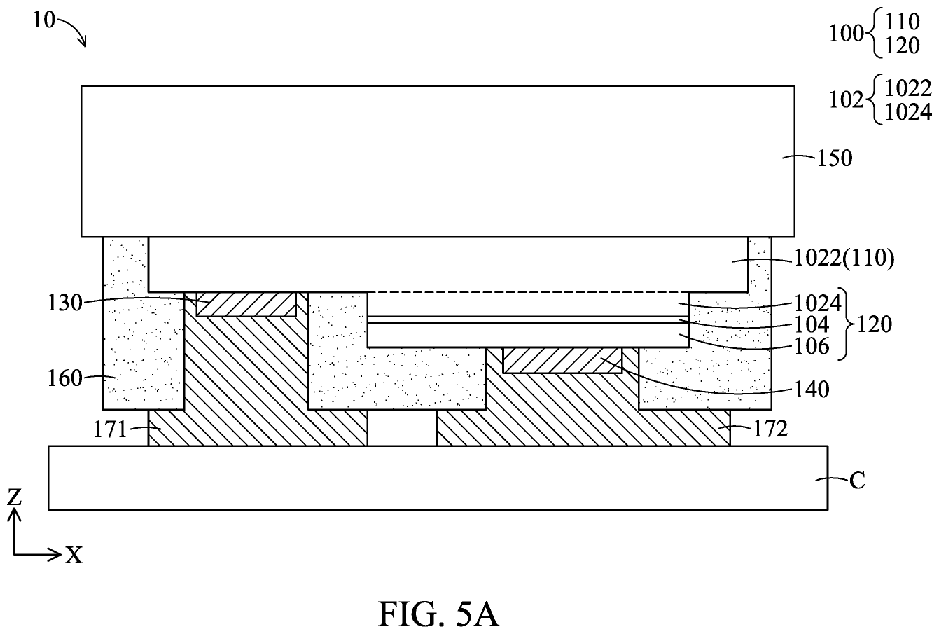

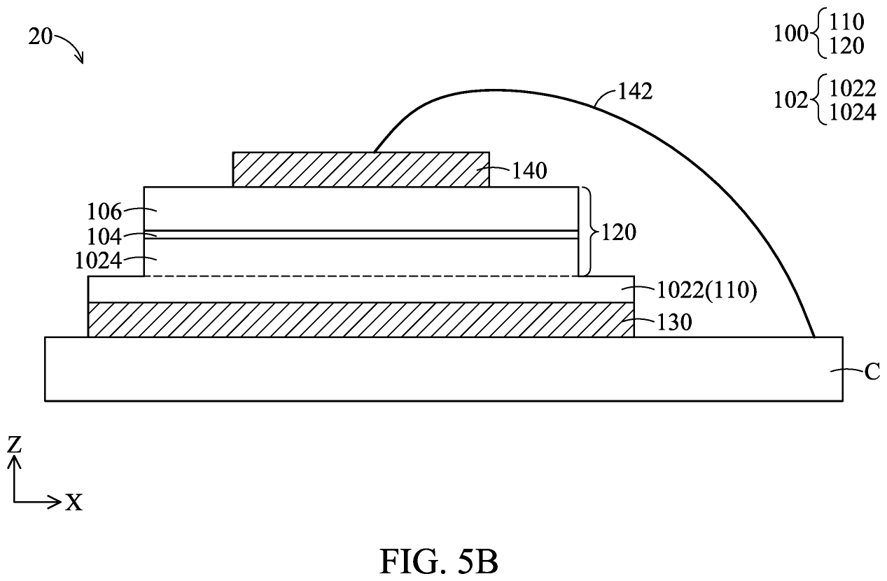

FIGS. 5A and 5B respectively show cross-sectional views of the optoelectronic semiconductor element 10 and 20 bonded to carriers C, in accordance with some embodiments of the present disclosure.

Referring to FIG. 5A, the optoelectronic semiconductor element 10 is flipped and bonded to the carrier C, and the optoelectronic semiconductor element 10 electrically connects to the carrier C through the first electrode 171 and the second electrode 172, so as the optoelectronic semiconductor element 10 is electrically connected to an external circuit. In an embodiment, the optoelectronic semiconductor element 10 may not have the substrate 150.

In FIG. 5B, the first metal layer 130 of the optoelectronic semiconductor element 20 is electrically bonded to the carrier C, and the second metal layer 140 is electrically bonded to the carrier C through a wire 142, so as the optoelectronic semiconductor element 20 is electrically connected to the external circuit. In FIG. 5B, the optoelectronic semiconductor element 20 is fixed on the carrier C after removing the substrate 150, but the present disclosure is not limited thereto. In another embodiment, the optoelectronic semiconductor element 20 with the substrate 150 may also be fixed on the carrier C, and the substrate 150 is located between the first electrode 130 and the carrier C. The carrier C may be a printed circuit board (PCB), thin film transistor glass (TFT glass), complementary metal oxide semiconductor (CMOS) substrate or other suitable materials.

In summary, the present disclosure provides optoelectronic semiconductor elements with various configurations, which are used to solve the problems derived from the influence of the original dimensional design and manufacturing process of the micro-LED elements during the manufacturing process. By designing the structural appearance of the optoelectronic semiconductor element according to the embodiments of the present disclosure, the accuracy of the dimension and appearance of the element can be improved. For example, the appearance abnormality of the micro-LED chip can be reduced and the product yield can be improved. At the same time, the yield and stability of the micro-LED chip during mass transfer can also be enhanced.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optoelectronic semiconductor element, comprising:
a semiconductor stack comprising a first portion and a second portion on the first portion, and the second portion comprising an active region; and
a first metal layer located on the first portion and electrically connected to the first portion;
wherein, from a top view of the optoelectronic semiconductor element, the first portion has a first pattern, the second portion has a second pattern, and the first metal layer has a third pattern, wherein a first area ratio of the third pattern to the first pattern is from 0.5% to 10%.

2. The optoelectronic semiconductor element as claimed in claim 1, wherein the first pattern has a first rounded corner with a first curvature radius R1, and the second pattern has a second rounded corner with a second curvature radius R2, and R1≥R2.

3. The optoelectronic semiconductor element as claimed in claim 2, wherein the third pattern has a third rounded corner with a third curvature radius R3, and R1≥R3.

4. The optoelectronic semiconductor element as claimed in claim 2, wherein the first curvature radius R1 is 0.5 μm-5 μm, and the second curvature radius R2 is 0.2 μm-2 μm.

5. The optoelectronic semiconductor element as claimed in claim 1, wherein the first pattern is substantially rectangular and the third pattern has a third rounded corner, and the first pattern has several diagonals not overlapping with the third pattern.

6. The optoelectronic semiconductor element as claimed in claim 1, further comprising:
a second metal layer located on the second portion and electrically connected to the second portion, wherein the first metal layer and the second metal layer are on the same side of the semiconductor stack.

7. The optoelectronic semiconductor element as claimed in claim 6, further comprising:
a first electrode electrically connected to the first metal layer; and
a second electrode electrically connected to the second metal layer;
wherein the first electrode has a first top surface and the second electrode has a second top surface, and the first top surface and the second top surface have the same elevation.

8. The optoelectronic semiconductor element as claimed in claim 1, wherein the optoelectronic semiconductor element comprises a device width W, and a second shortest distance W2 is between the first pattern and the second pattern, and W/W2 is 3-80.

9. The optoelectronic semiconductor element as claimed in claim 8, wherein W/W2 is 15-30.

10. The optoelectronic semiconductor element as claimed in claim 8, wherein the second shortest distance W2 is 0.2 μm-5 μm.

11. The optoelectronic semiconductor element as claimed in claim 8, wherein a third shortest distance W3 is between the second pattern and the third pattern, and W3≥W2.

12. The optoelectronic semiconductor element as claimed in claim 1, wherein the optoelectronic semiconductor element comprises a device width W, and a fourth shortest distance W4 is between the first pattern and the third pattern, and W/W4 is 2.5-30.

13. The optoelectronic semiconductor element as claimed in claim 12, wherein a second shortest distance W2 is between the first pattern and the second pattern, and W4≥W2.

14. The optoelectronic semiconductor element as claimed in claim 12, wherein the fourth shortest distance W4 is 0.5 μm-6 μm.

15. The optoelectronic semiconductor element as claimed in claim 1, wherein the optoelectronic semiconductor element comprises a device width W, and the third pattern comprises a fifth width W5, and W/W5 is 1.1-10.

16. An optoelectronic semiconductor element, comprising:
a semiconductor stack comprising a first portion and a second portion, and the second portion comprising an active region;
a first metal layer electrically connected to the first portion; and
a second metal layer electrically connected to the second portion, wherein the semiconductor stack is located between the first metal layer and the second metal layer;
wherein, from a top view of the optoelectronic semiconductor element, the first portion has a first pattern, the second portion has a second pattern, the first metal layer has a third pattern, and the second metal layer has a fourth pattern, wherein a second area ratio of the fourth pattern to the first pattern is from 0.5% to 10%.

17. The optoelectronic semiconductor element as claimed in claim 16, wherein the first pattern is circular or elliptical, and the first pattern has a first curvature radius R1.

18. The optoelectronic semiconductor element as claimed in claim 17, wherein the second pattern and the fourth pattern are circular or elliptical, the second pattern has a second curvature radius R2, the fourth pattern has a fourth curvature radius R4, wherein the first curvature radius R1 of the first pattern is larger than or equal to the second curvature radius R2 of the second pattern, and the first curvature radius R1 of the first pattern is larger than or equal to the fourth curvature radius R4 of the fourth pattern.

19. The optoelectronic semiconductor element as claimed in claim 17, wherein the third pattern is circular or elliptical, and the third pattern has a third curvature radius R3, wherein the first curvature radius R1 of the first pattern is larger than or equal to the third curvature radius R3 of the third pattern.

20. The optoelectronic semiconductor element as claimed in claim 16, wherein the first pattern, the second pattern, and the fourth pattern are concentric to each other.
